(19) United States
(12) Patent Application Publication
(10) Pub. No.: US 2025/0246464 A1
(43) Pub. Date: Jul. 31, 2025

(54) Article Transport Facility

(71) Applicant: Daifuku Co., Ltd., Osaka-shi (JP)

(72) Inventors: Ryoji Kishi, Hinocho (JP); Kouji Ueba, Hinocho (JP)

(21) Appl. No.: 19/038,812

(22) Filed: Jan. 28, 2025

(30) Foreign Application Priority Data
Jan. 29, 2024 (JP) 2024-011194

(51) Int. Cl. H01L 21/67; H01L 21/677

(52) U.S. Cl. CPC H01L 21/67288; H01L 21/67724; H01L 21/6773

(57) ABSTRACT

An article transport facility includes a control system configured to classify inspection results on transport vehicles which inspection results are acquired by an inspection apparatus into a normal level, a transport-performable abnormal level as an abnormal level which does not reach the normal level but in which a corresponding transport vehicle is able to continue transporting an article, and a transport-unperformable abnormal level as an abnormal level in which a corresponding transport vehicle is not able to continue transporting the article, and to perform an exit process on a transport vehicle having an inspection result classified as the transport-unperformable abnormal level, in such a manner as to cause the transport vehicle to exit out of a path via an exit section in the path.

### CROSS-REFERENCE TO RELATED APPLICATION

This application claims priority to Japanese Patent Application No. 2024-011194 filed Jan. 29, 2024, the disclosure of which is hereby incorporated by reference in its entirety.

### BACKGROUND OF THE INVENTION

### 1. Field of the Invention

The present invention relates to an article transport facility including a plurality of transport vehicles each configured to transport an article.

### 2. Description of Related Art

An article transport facility including a plurality of transport vehicles each configured to transport an article is known. Japanese Unexamined Patent Application Publication No. 2023-097841 (JP 2023-097841) discloses an article transport facility including a plurality of transport vehicles (10) each configured to move along a predetermined path (81a, 81b) and transport an article (100).

JP 2023-097841 describes a collecting mechanism configured to collect a transport vehicle that stops abnormally. However, in order to prevent a decrease in article transport efficiency in the article transport facility as much as possible, it is desirable to find an abnormality in a transport vehicle by inspection before the transport vehicle stops abnormally and to cause the transport vehicle to exit from a path. However, when a criterion for exit in the inspection is too low, an abnormal stop of a transport vehicle easily occurs in the path, but when the criterion for exit is too high, the number of transport vehicles in the path decreases. In any case, there is such a problem that the article transport efficiency in the article transport facility easily decreases.

### SUMMARY OF THE INVENTION

In view of the foregoing, it is desired to achieve an article transport facility which suitably performs maintenance of transport vehicles and which can reduce the possibility of a decrease in article transport efficiency in the article transport facility.

An article transport facility according to this disclosure is an article transport facility including: a plurality of transport vehicles each configured to move along a predetermined path and transport an article; an inspection apparatus disposed in an inspection area in the path and configured to perform an inspection on the transport vehicles; and a control system configured to control the plurality of transport vehicles and the inspection apparatus. The control system is configured to classify inspection results on the transport vehicles which inspection results are acquired by the inspection apparatus into a normal level, a transport-performable abnormal level as an abnormal level which does not reach the normal level but in which a corresponding transport vehicle is able to continue transporting the article, and a transport-unperformable abnormal level as an abnormal level in which a corresponding transport vehicle is not able to continue transporting the article, and to perform an exit process on a transport vehicle having an inspection result classified as the transport-unperformable abnormal level, in such a manner as to cause the transport vehicle to exit out of the path via an exit section in the path.

In this configuration, the exit process is performed on a transport vehicle having an inspection result classified as the transport-unperformable abnormal level. Accordingly, it is possible to immediately cause the transport vehicle that cannot continue transporting the article to exit from the path and to perform maintenance or repair on the transport vehicle appropriately. In addition, in this configuration, a transport vehicle having an inspection result not classified as the normal level but classified as the abnormal level in which the transport vehicle can continue transporting the article is not targeted for the exit process, so that the transport vehicle can continue transporting the article. This accordingly makes it possible to reduce such a possibility that the number of transport vehicles targeted for the exit process increases too much, and article transport efficiency in the article transport facility decreases.

Further features and advantages of the technology according to this disclosure will become clearer by the following illustrative and nonlimiting description of embodiments to be described with reference to the drawings.

### BRIEF DESCRIPTION OF THE DRAWINGS

FIG. 1 is a drawing illustrating an example of an article transport facility;

FIG. 2 is a drawing illustrating an example of a transport vehicle in FIG. 1;

FIG. 3 is a perspective view of the transport vehicle in FIG. 1;

FIG. 4 is a drawing illustrating an example of a holder inspection device in FIG. 1;

FIG. 5 is a drawing illustrating an example of a control system in the article transport facility in FIG. 1; and

FIG. 6 is a drawing illustrating an example of a control in the control system in FIG. 5.

### DESCRIPTION OF THE INVENTION

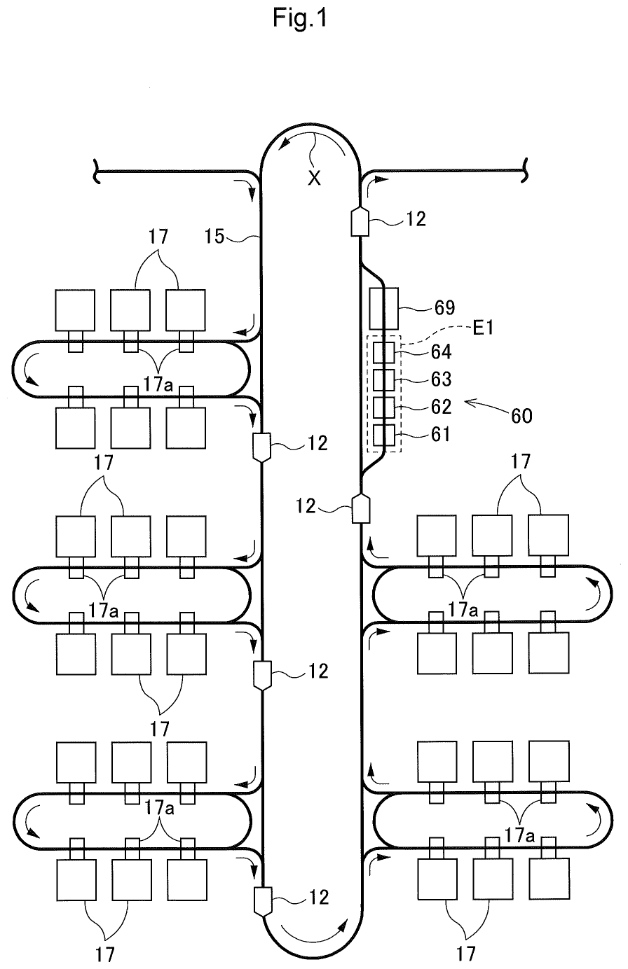

The following describes an article transport facility 10 according to a first embodiment with reference to the drawings. FIG. 1 is a top plan view illustrating an example of the article transport facility 10 and a path 15. The article transport facility 10 includes a plurality of transport vehicles 12 each configured to move along a predetermined path 15 and transport an article W. Here, the longitudinal direction of the path 15 is defined as a path direction X, and the width direction of the path 15 is defined as a width direction Y (see FIG. 3). The width direction Y is a direction perpendicular to both the path direction X and an up-down direction Z that is a vertical direction.

The transport vehicle 12 travels along the path 15 and transports the article W. Examples of the transport vehicle 12 include an unmanned transport vehicle, a transport vehicle configured to transport a staff and an article, an autonomous transport vehicle, a non-autonomous transport vehicle, an overhead transport vehicle, a transport vehicle configured to travel on a floor face, a sorting wagon, a magnetic levitation transport vehicle, and so on.

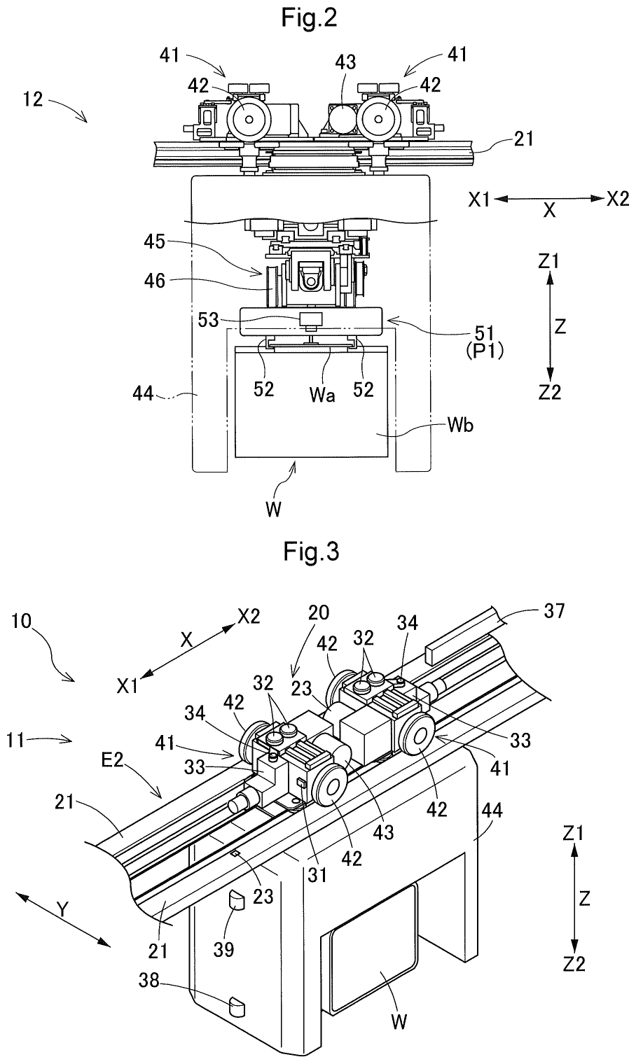

The path 15 may be formed physically or may be formed virtually. Examples of the path 15 include rails, a two-dimensional code, an RF (Radio Frequency) tag, a magnetic tape, and a path formed in a passage shape or the like. In the present embodiment, the path 15 is formed by a pair of traveling rails 21 (see FIGS. 2, 3) disposed at an interval in the width direction Y. The traveling rails 21 are supported on a ceiling in a suspended manner. In the present embodiment, the path 15 is a one-way path but may not be a one-way path.

In the present embodiment, a plurality of transfer target spots 17 is disposed along the path 15. Examples of the transfer target spot 17 include a processor configured to perform processing on the article W, storage equipment configured to store the article W, a support base adjacent to a storage shelf configured to store the article W, a buffer configured to temporarily hold the article W, a transport device for shipment, a transport device for receipt, and so on. In the present embodiment, the transfer target spot 17 is provided with an article support base 17a configured to support the article W. The transport vehicle 12 transports an article W before processing by the processor from a transport source (not illustrated) to the article support base 17a, and transports an article W after processing by the processor from the article support base 17a to a transport destination (not illustrated), for example.

FIG. 2 is a side view illustrating an example of the transport vehicle 12 and the article W. The article W is not limited particularly, but in the present embodiment, the article W is a container in which a processing object targeted for the processing by the processor is stored. In the present embodiment, the above-mentioned “processing on the article” means processing on a processing object stored in the article W. The article W may be a wafer storage container (so-called FOUP: Front Opening Unified Pod) for storing wafers, or a reticle storage container (so-called reticle pod) for storing reticles. In a case where the article W is a FOUP, the processing object is a wafer. In a case where the article W is a reticle pod, the processing object is a reticle.

The article W includes a flange section Wa provided in an upper end portion of the article W and held by the transport vehicle 12, a storage section Wb located below the flange section Wa and configured to store a plurality of semiconductor substrates, and a removable lid (not illustrated) configured to block a substrate entrance which is provided on the front surface of the storage section Wb and through which the substrates are taken in and out. The transport vehicle 12 holds the flange section Wa in a suspended manner and transports the article W.

FIG. 3 is a perspective view illustrating an example of the transport vehicle 12 and the path 15. A guide rail 37 is provided for part of the path 15. The guide rail 37 is disposed on an upper side Z1 relative to the traveling rails 21. The guide rail 37 is disposed between the pair of traveling rails 21 disposed at an interval in the width direction Y, as viewed vertically.

The path 15 is provided with a plurality of information retainers 23 each configured to retain positional information of its corresponding installation position. The information retainers 23 are discretely disposed along the path 15. Examples of the information retainer 23 include a one-dimensional barcode, a two-dimensional barcode, a number, a character, an image sign, a wireless tag, and so on. The information retainer 23 is provided for the traveling rail 21, the guide rail 37, a holding member for holding the traveling rails 21 or the guide rail 37, a road surface, or the like, for example.

The transport vehicle 12 includes a reader 31 configured to read positional information retained by the information retainer 23 and recognizes its own position in the path 15 based on information read by the reader 31. Examples of the reader 31 include a barcode reader, an image reader, a character reader for reading a number or a character, and a radio identification device. The transport vehicle 12 recognizes its current position, for example, based on the positional information read by the reader 31, and a travel distance after the reader 31 reads the positional information. The travel distance of the transport vehicle 12 is measured by use of a rotary encoder, for example. Note that the transport vehicle 12 can be configured to recognize its current position based on an output from a positioning device such as a GNSS (Global Navigation Satellite System) receiver.

The transport vehicle 12 includes a guided section 32 to be guided by the guide rail 37 in contact with the guide rail 37 from either side in the width direction Y, and a guide drive unit 33 (for example, a solenoid or an electric motor) configured to move the guided section 32 in the width direction Y. The movement of the guided section 32 in the width direction Y by the guide drive unit 33 is performed, for example, by driving only the guided section 32 in the width direction Y, or by driving the guided section 32 in the width direction Y together with a support for supporting the guided section 32.

The transport vehicle 12 includes a movement detection sensor 34 configured to detect movement of the guided section 32 in the width direction Y. A control system 70 (described later) detects the guided section 32 moving in the width direction Y, by acquiring a detection result on the movement of the guided section 32 in the width direction Y from the movement detection sensor 34.

The transport vehicle 12 includes an obstacle sensor 38 configured to detect an obstacle present on a downstream side X1 in the path direction X. When an obstacle is detected by the obstacle sensor 38 during traveling of the transport vehicle 12, for example, the transport vehicle 12 slows down or stops. Examples of the obstacle include an operator, an operation robot, a foreign substance, other transport vehicles 12, and so on in the path 15. Examples of the obstacle sensor 38 include an optical sensor, an ultrasonic sensor, an image sensor, a millimeter wave sensor, a laser sensor, and so on. The detection result from the obstacle sensor 38 is transmitted to the control system 70 (described later). In the present embodiment, the obstacle sensor 38 can measure a distance to the obstacle by reflected light caused by projecting light toward the downstream side X1 in the path direction X. The obstacle sensor 38 is disposed on the front surface of the transport vehicle 12.

The transport vehicle 12 includes a collision prevention sensor 39 configured to detect another transport vehicle 12 present on the downstream side X1 in the path direction X. Examples of the collision prevention sensor 39 include an optical sensor, an ultrasonic sensor, an image sensor, a millimeter wave sensor, a laser sensor, and so on. The collision prevention sensor 39 is disposed on the front surface of the transport vehicle 12 and is closer to the traveling rail 21 than the obstacle sensor 38 in the up-down direction Z. The collision prevention sensor 39 projects light toward the downstream side X1 in the path direction X and detects reflection from a reflection member disposed on the surface of the another transport vehicle 12 which surface faces an upstream side X2, for example. The collision prevention sensor 39 is disposed on the front surface of the transport vehicle 12.

The transport vehicle 12 includes a travel unit 41 configured to travel along the path 15. The travel unit 41 includes a first travel unit on the downstream side X1 and a second travel unit on the upstream side X2. The travel unit 41 includes travel wheels 42 configured to roll on respective travel surfaces (surfaces facing the upper side Z1) of the traveling rails 21, and a traveling drive unit 43 (e.g., an electric motor such as a servomotor) configured to rotate the travel wheels 42. When the travel wheels 42 are rotated by the traveling drive unit 43, the travel unit 41 travels on the traveling rails 21. The transport vehicle 12 includes a cover 44 supported in a suspended manner by the travel unit 41.

The transport vehicle 12 includes a holder 51 configured to hold the article W. The holder 51 is coupled to the travel unit 41. The article W is stored in the holder 51 and transported by the transport vehicle 12. The holder 51 is disposed on a lower side Z2 relative to the travel unit 41 and supported by the travel unit 41.

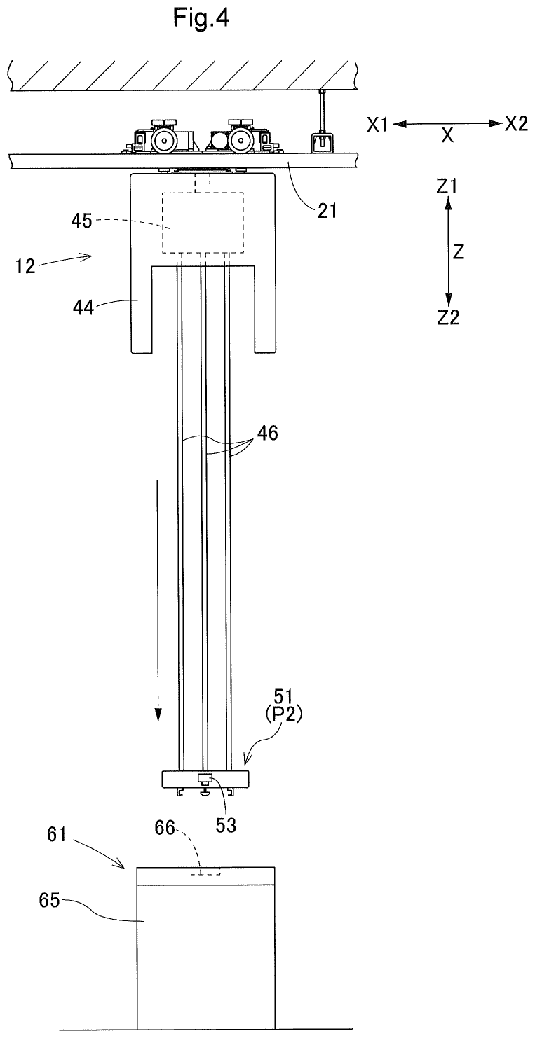

The transport vehicle 12 includes an in-vehicle lifting and lowering device 45 configured to lift and lower the holder 51 relative to the travel unit 41. The in-vehicle lifting and lowering device 45 lifts and lowers the holder 51 in the up-down direction Z between a travel position P1 (see FIG. 2) and a transfer position P2 (see FIG. 4). The in-vehicle lifting and lowering device 45 lifts and lowers the holder 51 in the up-down direction Z between the travel position P1 and the transfer position P2 by winding and unwinding a plurality of suspending members 46 while the holder 51 is suspended by the plurality of suspending members 46.

The travel position P1 is a position allowing the transport vehicle 12 to travel along the path 15, and the transfer position P2 is a position allowing the transport vehicle 12 to transfer the article W between the transfer target spot 17 and the holder 51. The holder 51 is disposed at a height corresponding to the article support base 17a in the transfer target spot 17 while the holder 51 is at the transfer position P2.

The holder 51 includes a pair of grip hooks 52 and a grip motor (not illustrated) configured to cause the pair of grip hooks 52 to approach and separate from each other. When the grip motor drives the pair of grip hooks 52 to approach or separate from each other, the pair of grip hooks 52 is switched between a gripping state in which the pair of grip hooks 52 grips the flange section Wa of the article W and an ungripping state where the pair of grip hooks 52 ungrips the flange section Wa.

The article transport facility 10 includes an inspection apparatus 60 configured to inspect the transport vehicle 12. The inspection apparatus 60 is disposed in an inspection area E1 in the path 15. The inspection area E1 may be one area, a plurality of continuous areas, or a plurality of non-continuous areas.

The inspection apparatus 60 is configured to perform an inspection on at least one inspection item. In the present embodiment, the inspection apparatus 60 is configured to perform an inspection on a plurality of inspection items. Examples of the inspection item of the transport vehicle 12 include a wheel abrasion inspection, an inspection on the obstacle sensor 38, an inspection on the collision prevention sensor 39, an inspection on the holder 51, an inspection on a wheel deterioration degree, an inspection on the movement detection sensor 34, an inspection on a vibrational state of the transport vehicle 12, an inspection on a vibrational state of the holder 51, an inspection on abnormal noise in the transport vehicle 12, an inspection on a storage battery in the transport vehicle 12, and so on.

The inspection apparatus 60 includes a holder inspection device 61 configured to perform an inspection on the holder 51, an abrasion inspection device 62 configured to perform a wheel abrasion inspection, an obstacle sensor inspection device 63 configured to perform an inspection on the obstacle sensor 38, and a collision prevention sensor inspection device 64 configured to perform an inspection on the collision prevention sensor 39. Examples of the wheel abrasion inspection include measurement of the diameter of the travel wheel 42, measurement of the diameter of a guide wheel as the guided section 32, and so on.

Examples of the inspection on the obstacle sensor 38 include measurement of a detective range in the up-down direction Z, measurement of a detective range in the width direction Y, measurement of the inclination of a laser in the up-down direction Z, measurement of the inclination of the laser in the width direction Y, measurement of the intensity of the laser, and so on. Examples of the inspection on the collision prevention sensor 39 include measurement of a detective range in the up-down direction Z, measurement of a detective range in the width direction Y, measurement of the inclination of the laser in the up-down direction Z, measurement of the inclination of the laser in the width direction Y, measurement of the intensity of the laser, and so on.

Examples of the inspection on the holder 51 include measurement of the inclination of the holder 51 around an axial center parallel to the path direction X at the travel position P1 or the transfer position P2, measurement of the inclination of the holder 51 around an axial center parallel to the width direction Y at the travel position P1 or the transfer position P2, measurement of the inclination of the holder 51 around an axial center parallel to the up-down direction Z at the travel position P1 or the transfer position P2, and so on.

FIG. 4 is a side view illustrating an example of the holder inspection device 61. The holder inspection device 61 includes an inspection table 65 provided with a detected object 66. The transport vehicle 12 includes a position detecting section 53 configured to detect the position of the detected object 66 provided for the inspection table 65. The detected object 66 includes a two-dimensional code. The position detecting section 53 includes a two-dimensional image sensor. The inclination of the holder 51 in the path direction X, the width direction Y, or the up-down direction Z, the position of the holder 51 in the path direction X, the width direction Y, or the up-down direction Z at the travel position P1 or the transfer position P2, or the like is derived from an inclination, a distance, or the like of the detected object 66 relative to the position detecting section 53, for example. The inclination, the distance, or the like of the detected object 66 relative to the position detecting section 53 is derived from a size, an angle, a position, or the like of the detected object 66 captured by the position detecting section 53, for example.

As illustrated in FIG. 1, the path 15 includes an exit section 69 configured to cause the transport vehicle 12 to exit out of the path 15. The exit section 69 is provided on the downstream side X1 in the inspection area E1. In the example illustrated herein, the exit section 69 is disposed adjacent to the inspection area E1. Examples of the exit section 69 include a lifting and lowering device configured to cause the transport vehicle 12 to exit from the path 15, a transport device configured to cause the transport vehicle 12 to exit from the path 15, an exit path branching from the path 15, and so on.

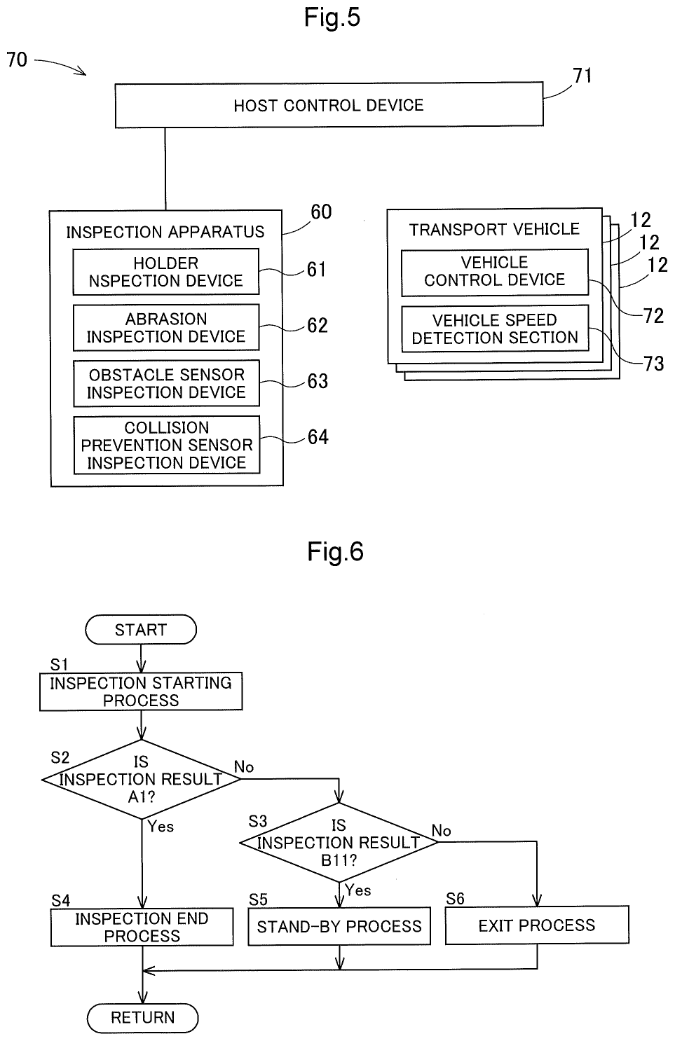

FIG. 5 is a control block diagram of the article transport facility 10. The article transport facility 10 includes the control system 70 configured to control the plurality of transport vehicles 12. Each function of the control system 70 is implemented by collaboration of hardware such as an arithmetic processing unit with a program executed on the hardware, for example. The whole control system 70 may be provided for the transport vehicle 12, or part of the control system 70 may be provided for the transport vehicle 12, and another part of the control system 70 may be provided for an external control device (a control device provided outside the transport vehicle 12 and communicable with the transport vehicle 12). The whole control system 70 may be provided for an external control device. Here, the external control device may not be one device and may be a set of a plurality of devices communicable with each other. The control system 70 controls traveling of each of the plurality of transport vehicles 12 to reach its destination. In the present embodiment, the control system 70 includes a host control device 71 provided outside the transport vehicle 12.

The transport vehicle 12 includes a vehicle control device 72 configured to control the guide drive unit 33, the traveling drive unit 43, the in-vehicle lifting and lowering device 45, and so on. In a case where at least part of the control system 70 is provided for an external control device, the vehicle control device 72 of the transport vehicle 12 works in response to a command from the external control device. In a case where at least part of the control system 70 is provided for the transport vehicle 12, the vehicle control device 72 of the transport vehicle 12 may constitute the at least part of the control system 70.

The article transport facility 10 includes a vehicle speed detection section 73 configured to detect a traveling speed of the transport vehicle 12. The vehicle speed detection section 73 is provided for the transport vehicle 12. The vehicle speed detection section 73 detects the traveling speed of the transport vehicle 12 by measuring a rotation speed of the travel wheels 42.

The control system 70 is configured to control the inspection apparatus 60. The control of the inspection apparatus 60 and the control of the transport vehicle 12 may be performed by different control devices in the control system 70 or may be performed by the same control device. The inspection apparatus 60 may be provided with part of the control system 70.

The control system 70 restricts a number Ns of transport vehicles 12 to be targeted for the inspection performed by the inspection apparatus 60 within a predetermined period Ts, to a predetermined inspection upper limit number Nsm or less. The predetermined period Ts may be a value to be changed manually by a manager, a value to be changed automatically by the control system 70, or a fixed value. Examples of the predetermined period Ts include 1 hour, 6 hours, 12 hours, 1 day, 7 days, and so on. Examples of the inspection upper limit number Nsm include a value determined based on the operating status of the inspection apparatus 60, a value determined based on the operating status of the article transport facility 10, a value determined based on the operating status of the plurality of transport vehicles 12 in the article transport facility 10, and so on.

The control system 70 can derive the travel position P1 of the transport vehicle 12 based on information read by the reader 31, derive an inclination, a position, or the like of the holder 51 based on information detected by the position detecting section 53, derive a traveling speed of the transport vehicle 12 based on information detected by the vehicle speed detection section 73, and so on, for example.

FIG. 6 is a flowchart illustrating an example of a transport vehicle inspecting step (process) performed by the control system 70. In the present embodiment, the transport vehicle inspecting step is performed regularly but may be performed manually, for example. The transport vehicle inspecting step may be performed during a non-operating time of the article transport facility 10 during which non-operating time the transport vehicle 12 does not transport the article W, or may be performed during an operating time of the article transport facility 10 during which operating time the transport vehicle 12 transports the article W. The control system 70 moves the transport vehicle 12 to the inspection area E1 and performs an “inspection starting process S1” of starting the inspection performed by the inspection apparatus 60. In the present embodiment, the inspection starting process S1 is performed on the transport vehicle 12 that is transporting no article W.

The control system 70 classifies an inspection result on the transport vehicle 12 which inspection result is acquired from the inspection apparatus 60 into a normal level A1, a transport-performable abnormal level B11 as an abnormal level B1 which does not reach the normal level A1 but in which the transport vehicle 12 can continue transporting the article W, or a transport-unperformable abnormal level B12 as an abnormal level B1 in which the transport vehicle 12 cannot continue transporting the article W.

The control system 70 classifies itemized inspection results as respective inspection results on a plurality of inspection items into the normal level A1, the transport-performable abnormal level B11, and the transport-unperformable abnormal level B12. Based on a plurality of itemized inspection results, the control system 70 classifies the inspection result on the transport vehicle 12 into the normal level A1, the transport-performable abnormal level B11, or the transport-unperformable abnormal level B12. In the present embodiment, the control system 70 classifies the inspection result on the transport vehicle 12 as the transport-unperformable abnormal level B12 in a case where at least one itemized inspection result is classified as the transport-unperformable abnormal level B12.

An inspection result acquired by the inspection apparatus 60 includes classification information, and the control system 70 classifies the inspection result into any of three levels based on the classification information. In the present embodiment, the classification information is an index D indicative of an inspection result acquired by the inspection apparatus 60 and increasing as an abnormal level increases. When the index D is less than a first determination value Da1, the control system 70 classifies the inspection result as the normal level A1. When the index D is equal to or more than the first determination value Da1 but less than a second determination value Da2, the control system 70 classifies the inspection result as the transport-performable abnormal level B11. When the index D is equal to or more than the second determination value Da2, the control system 70 classifies the inspection result as the transport-unperformable abnormal level B12. Here, the second determination value Da2 is a value larger than the first determination value Da1.

In the present embodiment, the index D is an index indicative of an itemized inspection result and is a value increasing as an abnormal level increases. Examples of the index D include the diameter of the travel wheel 42, the inclination of the laser of the obstacle sensor 38, the inclination of the laser of the collision prevention sensor 39, an inclination of the holder 51, the volume of abnormal noise, and so on. Note that, in a case where an abnormal level increases as a measured value is smaller in an itemized inspection, an inverse number of the measured value may be taken as the index D. The index D may be an index indicative of an itemized inspection result and a value that decreases as an abnormal level increases, and the second determination value Da2 may be a value smaller than the first determination value Da1.

In the present embodiment, the above classification for the itemized inspection results and the inspection result on the transport vehicle 12 is performed in the inspection starting process S1, but the classification may be performed in a normal determination process S2 and in a transport-performability determination process S3 (described later).

The control system 70 performs the “normal determination process S2” of determining whether the inspection result on the transport vehicle 12 is classified as the normal level A1 or not. In a case where the inspection result on the transport vehicle 12 is classified as the normal level A1, an inspection end process S4 (described later) is performed on the transport vehicle 12. In a case where the inspection result on the transport vehicle 12 is not classified as the normal level A1, the transport-performability determination process S3 (described later) is performed on the transport vehicle 12.

When the inspection result on the transport vehicle 12 is classified as the normal level A1, the control system 70 moves the transport vehicle 12 out of the inspection area E1. In the present embodiment, the control system 70 performs the “inspection end process S4” of moving the transport vehicle 12 out of the inspection area E1 so that the transport vehicle 12 can start to transport the article W. Due to the inspection end process S4, the transport vehicle 12 moves to, for example, a transport source of an article W to be transported subsequently, a charge position for the transport vehicle 12, a charge stand-by position for the transport vehicle 12, and the like, which are set in the path 15. In the present embodiment, the transport vehicle 12 travels by itself in the inspection end process S4 but may be pulled or moved by other means.

When the inspection result on the transport vehicle 12 is classified as the transport-performable abnormal level B11, the control system 70 moves the transport vehicle 12 out of the inspection area E1. In the present embodiment, the control system 70 performs the “transport-performability determination process S3” of determining whether the inspection result on the transport vehicle 12 is classified as the transport-performable abnormal level B11 or not. In a case where the inspection result on the transport vehicle 12 is classified as the transport-performable abnormal level B11, the control system 70 performs a “stand-by process S5” of causing the transport vehicle 12 to wait. In a case where the inspection result on the transport vehicle 12 is not classified as the transport-performable abnormal level B11, the inspection result on the transport vehicle 12 is classified as the transport-unperformable abnormal level B12, and therefore, the control system 70 performs an exit process S6 (described later) on the transport vehicle 12.

Due to the stand-by process S5, the transport vehicle 12 moves from the inspection area E1 and waits at a stand-by position for the transport vehicle 12 which stand-by position is set in the path 15, the inspection area E1, a maintenance area (not illustrated), or the like, for example. The stand-by position may be a charge stand-by position for the transport vehicle 12. In the present embodiment, the transport vehicle 12 travels by itself in the stand-by process S5 but may be pulled or moved by other means.

The control system 70 gives priority to an inspection on the transport vehicle 12 classified as the transport-performable abnormal level B11 over the transport vehicle 12 classified as the normal level A1 in a subsequent transport vehicle inspecting step. For example, the control system 70 sets a period until the subsequent inspection starting process S1 to be shorter for the transport vehicle 12 having an inspection result classified as the transport-performable abnormal level B11 than for the transport vehicle 12 classified as the normal level A1.

The control system 70 performs the “exit process S6” of causing the transport vehicle 12 having an inspection result classified as the transport-unperformable abnormal level B12 to exit out of the path 15 via the exit section 69 in the path 15.

Although not illustrated in FIG. 6, in a case where a number N2 of transport vehicles 12 targeted for the exit process S6 (a first exit process) due to the inspection result being classified as the transport-unperformable abnormal level B12 is less than a predetermined exit upper limit number Nmax, the control system 70 also performs the exit process S6 (a second exit process) on the transport vehicle 12 having an inspection result classified as the transport-performable abnormal level B11 until a number N of transport vehicles 12 subjected to the exit process S6 reaches the exit upper limit number Nmax.

The transport vehicle 12 subjected to the exit process S6 (the first exit process and the second exit process) moves to the maintenance area (not illustrated), and maintenance or repair is performed on the transport vehicle 12, for example. In the present embodiment, a lifting and lowering device in the exit section 69 is used to move the transport vehicle 12 in the exit process S6, but the transport vehicle 12 may travel by itself or may be pulled or moved by other means.

In a case where the number N2 of transport vehicles 12 targeted for the exit process S6 due to the inspection result being classified as the transport-unperformable abnormal level B12 exceeds the predetermined exit upper limit number Nmax, the control system 70 performs the exit process S6 on N2—number of transport vehicles 12 classified as the transport-unperformable abnormal level B12.

The exit upper limit number Nmax is set, for example, based on maintenance and repair capacity in the maintenance area, the operating status of the article transport facility 10, the operating status of the plurality of transport vehicles 12 in the article transport facility 10, and the like. The exit upper limit number Nmax may be a value to be changed manually by a manager, a value to be changed automatically by the control system 70, or a fixed value. In a case where some transport vehicles 12 return to the path 15 after maintenance or repair, the number N of transport vehicles 12 subjected to the exit process S6 is a value acquired by subtracting the number of transport vehicles 12 returning to the path 15 from a previous number N of transport vehicles 12 subjected to the exit process S6, for example. Note that the number N of transport vehicles 12 subjected to the exit process S6, the number N1 of transport vehicles 12 having an inspection result classified as the transport-performable abnormal level B11, the number N2 of transport vehicles 12 having an inspection result classified as the transport-unperformable abnormal level B12, or the like may be the number of transport vehicles 12 within a given period of time, e.g., 12 hours, 24 hours, 3 days, 7 days, or the like.

The control system 70 performs the exit process S6 on N2—number of transport vehicles 12 targeted for the exit process S6 due to the inspection result being classified as the transport-unperformable abnormal level B12. Then, in a case where the number N2 is less than the exit upper limit number Nmax, the control system 70 performs the exit process S6 on the same number of transport vehicles 12 as a number acquired by subtracting the number N2 from the exit upper limit number Nmax, among N1—number of transport vehicles 12 classified as the transport-performable abnormal level B11 and subjected to the stand-by process S5. The transport vehicles 12 not subjected to the exit process S6 among the N1—number of transport vehicles 12 classified as the transport-performable abnormal level B11 are subjected to the inspection end process S4.

Note that, in FIG. 6, the inspection end process S4 may be performed instead of the stand-by process S5, and the exit process S6 may be performed on the same number of transport vehicles 12 as a number acquired by subtracting the number N2 from the exit upper limit number Nmax, among the transport vehicles 12 classified as the transport-performable abnormal level B11 and subjected to the inspection end process S4. In this case, it is not necessary to provide the stand-by position for the transport vehicles 12 classified as the transport-performable abnormal level B11.

In a case where the number N2 of transport vehicles 12 targeted for the exit process S6 due to at least one itemized inspection result being classified as the transport-unperformable abnormal level B12 is less than the predetermined exit upper limit number Nmax, the control system 70 performs the exit process S6 preferentially on the transport vehicle 12 having a larger number of itemized inspection results classified as the transport-performable abnormal level B11 until the number N of transport vehicles 12 subjected to the exit process S6 reaches the exit upper limit number Nmax.

Note that, in a case where the number N2 of transport vehicles 12 targeted for the exit process S6 due to at least one itemized inspection result being classified as the transport-unperformable abnormal level B12 is less than the predetermined exit upper limit number Nmax, the control system 70 may perform the exit process S6 preferentially on the transport vehicle 12 with a smaller number of itemized inspection results classified as the transport-performable abnormal level B11 until the number N of transport vehicles 12 subjected to the exit process S6 reaches the exit upper limit number Nmax. In this case, the exit process S6 can be performed preferentially on the transport vehicles 12 more likely to require a short period for maintenance or repair.

In a case where a plurality of transport vehicles 12 has the same number of itemized inspection results classified as the transport-performable abnormal level B11, the control system 70 performs the exit process S6 preferentially on the transport vehicle 12 having a longer operating time after maintenance or repair.

When the number of transport vehicles 12 inspected within the predetermined period Ts reaches the inspection upper limit number Nsm, the inspection end process S4 is performed on the transport vehicles 12 waiting due to the stand-by process S5, and hereby, the transport vehicle inspecting step by the control system 70 is ended.

In the present embodiment, in a subsequent transport vehicle inspecting step, the transport vehicle 12 not inspected in a previous transport vehicle inspecting step is inspected by the inspection apparatus 60 in preference to the transport vehicle 12 inspected in the previous transport vehicle inspecting step. In the present embodiment, the transport vehicle 12 with more lapsed days, a longer operating time, a longer travel time, a longer travel distance, or the like from a previous inspection performed by the inspection apparatus 60 is inspected in preference to others.

In the present embodiment, in a subsequent transport vehicle inspecting step, the transport vehicle 12 which has been classified as the transport-performable abnormal level B11 and has not been subjected to the exit process S6 in a previous transport vehicle inspecting step is inspected by the inspection apparatus 60 in preference to the transport vehicle 12 classified as the normal level A1. In the present embodiment, in the subsequent transport vehicle inspecting step, the transport vehicle 12 classified as the normal level A1 is inspected by the inspection apparatus 60 in preference to the transport vehicle 12 subjected to the exit process S6 in the previous transport vehicle inspecting step.

The following describes the article transport facility 10 according to a second embodiment. The present embodiment is different from the first embodiment in that the control system 70 does not classify itemized inspection results into the transport-performable abnormal level B11 and the transport-unperformable abnormal level B12. The following mainly describes differences from the first embodiment. Note that points not described particularly are the same as those in the first embodiment.

In the present embodiment, the control system 70 classifies itemized inspection results as respective inspection results on the plurality of inspection items into the normal level A1 and the abnormal level B1. Based on the number of inspection items having an itemized inspection result classified as the abnormal level B1, the control system 70 classifies the inspection result on the transport vehicle 12 into the transport-performable abnormal level B11 or the transport-unperformable abnormal level B12.

In the present embodiment, the index D is an index indicative of an itemized inspection result and is a value increasing as an abnormal level increases. When the index D is less than a first determination value Db1, the control system 70 classifies the inspection result as the normal level A1. When the index D is equal to or more than the first determination value Db1, the control system 70 classifies the inspection result as the abnormal level B1.

In the present embodiment, when an inspection item having an itemized inspection result classified as the abnormal level B1 is less than a second determination value Db2, the control system 70 classifies the inspection result on the transport vehicle 12 as the transport-performable abnormal level B11. When the inspection item having the itemized inspection result classified as the abnormal level B1 is equal to or more than the second determination value Db2, the control system 70 classifies the inspection result on the transport vehicle 12 as the transport-unperformable abnormal level B12.

In the present embodiment, in a case where the number N2 of transport vehicles 12 targeted for the exit process S6 due to the inspection result being classified as the transport-unperformable abnormal level B12 is less than the predetermined exit upper limit number Nmax, the control system 70 performs the exit process S6 preferentially on the transport vehicle 12 having a larger or smaller number of inspection items whose itemized inspection results are classified as the abnormal level B1, among the transport vehicles 12 targeted for the exit process S6 as being classified as the transport-performable abnormal level B11, until the number N of transport vehicles 12 subjected to the exit process S6 reaches the exit upper limit number Nmax.

In the present embodiment, in a case where a plurality of transport vehicles 12 has the same number of itemized inspection results classified as the abnormal level B1, the control system 70 performs the exit process S6 preferentially on the transport vehicle 12 having a longer operating time after maintenance or repair.

The following describes the article transport facility 10 according to a third embodiment. The following mainly describes differences from the first embodiment. The present embodiment is different from the first embodiment in that, instead of considering the number of itemized inspection results classified as the transport-performable abnormal level B11, the transport vehicle 12 having a high-priority inspection item classified as the transport-performable abnormal level B11 is given priority to. Note that points not described particularly are the same as those in the first embodiment.

In the present embodiment, a plurality of inspection items is prioritized. In a case where the number N2 of transport vehicles 12 targeted for the exit process S6 due to at least one itemized inspection result being classified as the transport-unperformable abnormal level B12 is less than the predetermined exit upper limit number Nmax, the control system 70 performs the exit process S6 preferentially on the transport vehicle 12 having a high-priority inspection item whose itemized inspection result is classified as the transport-performable abnormal level B11, until the number N of transport vehicles 12 subjected to the exit process S6 reaches the exit upper limit number Nmax.

Examples of the priority in the inspection items are as follows: any one or more of the inspection on the holder 51 and the inspections on the obstacle sensor 38 and the collision prevention sensor 39 are prioritized over the inspection on the travel wheel 42; any one or more of the inspection on the travel wheel 42 and the inspections on the obstacle sensor 38 and the collision prevention sensor 39 are prioritized over the inspection on the holder 51; and either one of or both the inspection on the travel wheel 42 and the inspection on the holder 51 are prioritized over the inspections on the obstacle sensor 38 and the collision prevention sensor 39.

In the present embodiment, in a case where respective highest-priority itemized inspection results of a plurality of transport vehicles 12 are all classified as the transport-performable abnormal level B11, the control system 70 performs the exit process S6 preferentially on the transport vehicle 12 in which the itemized inspection result of a secondly highest-priority inspection item is classified as the transport-performable abnormal level B11, among the plurality of transport vehicles 12.

Note that, in a case where the highest-priority itemized inspection results of the plurality of transport vehicles 12 are all classified as the transport-performable abnormal level B11, the control system 70 may perform the exit process S6 preferentially on the transport vehicle 12 having a longer operating time after maintenance or repair.

Note that, in a case where the highest-priority itemized inspection results of the plurality of transport vehicles 12 are all classified as the transport-performable abnormal level B11, the control system 70 may perform the exit process S6 preferentially on the transport vehicle 12 having a larger number of itemized inspection results classified as the transport-performable abnormal level B11.

Note that, in a case where the highest-priority itemized inspection results of the plurality of transport vehicles 12 are all classified as the transport-performable abnormal level B11, the control system 70 may perform the exit process S6 preferentially on the transport vehicle 12 having a smaller number of itemized inspection results classified as the transport-performable abnormal level B11.

One or more or two or more inspection items may be prioritized. For example, all the plurality of inspection items may be prioritized, or only one or two inspection items may be given priority to.

Next will be described other embodiments of the article transport facility.

(1) The above embodiment has described, as an example, the configuration in which the control system 70 classifies the inspection results on the transport vehicles 12 into three levels, i.e., the normal level A1, the transport-performable abnormal level B11, and the transport-unperformable abnormal level B12. However, the present invention is not limited to such an example, and the transport-performable abnormal level B11 or the transport-unperformable abnormal level B12 may be divided into a plurality of levels, so that the inspection results on the transport vehicles 12 may be classified into four or more levels, for example.

(2) The above embodiment has described, as an example, the configuration in which the exit upper limit number Nmax is set, and the control system 70 also performs the exit process S6 on the transport vehicle 12 classified as the transport-performable abnormal level B11. However, the present invention is not limited to such an example, and the control system 70 may not perform the exit process S6 on the transport vehicle 12 classified as the transport-performable abnormal level B11 and may set a period until a subsequent inspection starting process S1 to be shorter for the transport vehicle 12 classified as the transport-performable abnormal level B11 than for the transport vehicle 12 classified as the normal level A1, for example. For example, the exit upper limit number Nmax may not be set.

(3) The above embodiment has described, as an example, the configuration in which the inspection apparatus 60 performs the inspection in terms of a plurality of inspection items, and the control system 70 performs the exit process S6 on the transport vehicle 12 having at least one itemized inspection result classified as the transport-unperformable abnormal level B12. However, the present invention is not limited to such an example, and the transport vehicle 12 having one itemized inspection result classified as the transport-unperformable abnormal level B12 may be classified as the transport-performable abnormal level B11, for example. For example, the inspection apparatus 60 may perform the inspection in terms of only one inspection item.

(4) The above embodiment has described, as an example, the configuration in which the control system 70 restricts the number Ns of transport vehicles 12 to be targeted for the inspection performed by the inspection apparatus 60 within the predetermined period Ts, to the predetermined inspection upper limit number Nsm or less. However, the present invention is not limited to such an example, and the predetermined period Ts and the inspection upper limit number Nsm may not be set, and the transport vehicle inspecting step may be finished when the inspection by the inspection apparatus 60 for all the transport vehicles 12 in the path 15 is finished, for example. For example, when the number N of transport vehicles 12 subjected to the exit process S6 reaches the exit upper limit number Nmax, the transport vehicle inspecting step may be finished.

(5) The above embodiment has described, as an example, the configuration in which, in a subsequent transport vehicle inspecting step, the inspection apparatus 60 may inspect the transport vehicle 12 not inspected in a previous transport vehicle inspecting step, in preference to the transport vehicle 12 inspected in the previous transport vehicle inspecting step. However, the present invention is not limited to such an example, and the inspection apparatus 60 may preferentially inspect the transport vehicle 12 having a longer operating time after maintenance or repair, for example. The inspection apparatus 60 may preferentially inspect the transport vehicle 12 having a shorter operating time after maintenance or repair, for example. For example, the inspection apparatus 60 may perform the inspection such that the transport vehicles 12 are prioritized based on any one or more of the number of lapsed days, an operating time, a travel time, a travel distance, or the like from a previous inspection performed by the inspection apparatus 60.

(6) The above embodiment has described, as an example, the configuration in which the inspection apparatus 60 includes the holder inspection device 61, the abrasion inspection device 62, the obstacle sensor inspection device 63, and the collision prevention sensor inspection device 64. However, the present invention is not limited to such an example, and the inspection apparatus 60 may not include any one or more of the holder inspection device 61, the abrasion inspection device 62, the obstacle sensor inspection device 63, and the collision prevention sensor inspection device 64. For example, inspection devices of some types such as the obstacle sensor inspection device 63 and the collision prevention sensor inspection device 64 may be provided as one integrated device.

(7) The above embodiment has described, as an example, the configuration in which the exit section 69 is disposed on the downstream side X1 from the inspection area E1 and adjacent to the inspection area E1. However, the present invention is not limited to such an example, and the exit section 69 may be disposed at a position not adjacent to the inspection area E1, for example. For example, only one exit section 69 may be set in the path 15 or a plurality of exit sections 69 may be set in the path 15.

(8) The above embodiment has described, as an example, the configuration in which the inspection apparatus 60 is disposed in the inspection area E1 in the path 15. However, the present invention is not limited to such an example, and the inspection apparatus 60 may be provided for the transport vehicle 12, for example. For example, any one or more of the holder inspection device 61, the abrasion inspection device 62, the obstacle sensor inspection device 63, and the collision prevention sensor inspection device 64 may be provided for the transport vehicle 12.

(9) The above embodiment has described, as an example, the configuration in which the control system 70 performs the transport-performability determination process S3 after the normal determination process S2. However, the present invention is not limited to such an example, and the normal determination process S2 may be performed after the transport-performability determination process S3, for example. For example, a transport-unperformability determination process of determining whether or not the inspection result on the transport vehicle 12 is classified as the transport-unperformable abnormal level B12 may be performed instead of the normal determination process S2 or the transport-performability determination process S3.

(10) Note that the configuration disclosed in the above embodiments can be applied in combination with the configurations disclosed in other embodiments as long as no inconsistency occurs. In terms of other configurations, the embodiments disclosed in the present specification are also just examples in all respects. Accordingly, various modifications can be made appropriately as far as they do not deviate from the scope of this disclosure.

The following describes an article transport facility according to this disclosure.

An article transport facility according to one aspect is an article transport facility including: a plurality of transport vehicles each configured to move along a predetermined path and transport an article; an inspection apparatus disposed in an inspection area in the path and configured to perform an inspection on the transport vehicles; and a control system configured to control the plurality of transport vehicles and the inspection apparatus. The control system is configured to classify inspection results on the transport vehicles which inspection results are acquired by the inspection apparatus into a normal level, a transport-performable abnormal level as an abnormal level which does not reach the normal level but in which a corresponding transport vehicle is able to continue transporting the article, and a transport-unperformable abnormal level as an abnormal level in which a corresponding transport vehicle is not able to continue transporting the article, and to perform an exit process on a transport vehicle having an inspection result classified as the transport-unperformable abnormal level, in such a manner as to cause the transport vehicle to exit out of the path via an exit section in the path.

In this configuration, the exit process is performed on a transport vehicle having an inspection result classified as the transport-unperformable abnormal level. Accordingly, it is possible to immediately cause the transport vehicle that cannot continue transporting the article to exit from the path and to perform maintenance or repair on the transport vehicle appropriately. In addition, in this configuration, a transport vehicle having an inspection result not classified as the normal level but classified as the abnormal level in which the transport vehicle can continue transporting the article is not targeted for the exit process, so that the transport vehicle can continue transporting the article. This accordingly makes it possible to reduce such a possibility that the number of transport vehicles targeted for the exit process increases too much, and article transport efficiency in the article transport facility decreases.

As one aspect, in a case where the number of transport vehicles targeted for the exit process due to respective inspection results being classified as the transport-unperformable abnormal level is less than a predetermined exit upper limit number, the control system may perform the exit process on a transport vehicle having an inspection result classified as the transport-performable abnormal level until the number of transport vehicles subjected to the exit process reaches the exit upper limit number.

With this configuration, it is possible to appropriately restrain a decrease in the article transport efficiency in the article transport facility by restricting the number of transport vehicles targeted for the exit process by the exit upper limit number and to perform maintenance or repair on a transport vehicle having an inspection result classified as the transport-performable abnormal level as a relatively early stage.

As one aspect, the inspection apparatus may be configured to perform the inspection on each of the transport vehicles in terms of a plurality of inspection items. The control system may classify itemized inspection results as respective inspection results on the plurality of inspection items into the normal level, the transport-performable abnormal level, and the transport-unperformable abnormal level and performs the exit process on a transport vehicle having at least one itemized inspection result classified as the transport-unperformable abnormal level, and in a case where the number of transport vehicles targeted for the exit process due to at least one itemized inspection result being classified as the transport-unperformable abnormal level is less than a predetermined exit upper limit number, the control system may perform the exit process preferentially on a transport vehicle having a larger number of inspection items whose itemized inspection results are classified as the transport-performable abnormal level, until the number of transport vehicles subjected to the exit process reaches the exit upper limit number.

With this configuration, it is possible to appropriately restrain a decrease in the article transport efficiency in the article transport facility by restricting the number of transport vehicles targeted for the exit process by the exit upper limit number, and it is also possible to perform maintenance or repair preferentially on a transport vehicle having a larger number of inspection items whose itemized inspection results are classified as the transport-performable abnormal level, among transport vehicles having no inspection item whose itemized inspection result is classified as the transport-unperformable abnormal level. This accordingly makes it possible to perform maintenance or repair on a plurality of transport vehicles appropriately.

As one aspect, the inspection apparatus may be configured to perform the inspection on each of the transport vehicles in terms of a plurality of inspection items. The control system may classify itemized inspection results as respective inspection results on the plurality of inspection items into the normal level and an abnormal level, and the control system may classify an inspection result on a transport vehicle having at least one itemized inspection result classified as the abnormal level into the transport-performable abnormal level or the transport-unperformable abnormal level based on the number of inspection items whose itemized inspection results are classified as the abnormal level.

With this configuration, each of the transport vehicles can be appropriately classified into the transport-performable abnormal level or the transport-unperformable abnormal level based on a plurality of itemized inspection results of the each of the transport vehicles.

As one aspect, the control system may restrict the number of transport vehicles to be targeted for the inspection performed by the inspection apparatus within a predetermined period to a predetermined inspection upper limit number or less.

With this configuration, the number of transport vehicles to be inspected within the predetermined period can be restricted, thereby making it possible to restrain a decrease in transport efficiency which decrease is caused when a transport vehicle under inspection cannot transport the article.

The technical feature of the article transport facility according to this disclosure is also applicable to a transport vehicle inspection method or a transport vehicle inspection program.

What is claimed is:

1. An article transport facility, comprising:
a plurality of transport vehicles each configured to move along a predetermined path and transport an article;
an inspection apparatus disposed in an inspection area in the path and configured to perform an inspection on the transport vehicles; and
a control system configured to control the plurality of transport vehicles and the inspection apparatus,
wherein the control system is configured to classify inspection results on the transport vehicles which inspection results are acquired by the inspection apparatus into a normal level, a transport-performable abnormal level as an abnormal level which does not reach the normal level but in which a corresponding transport vehicle is able to continue transporting the article, and a transport-unperformable abnormal level as an abnormal level in which a corresponding transport vehicle is not able to continue transporting the article, and to perform an exit process on a transport vehicle having an inspection result classified as the transport-unperformable abnormal level, in such a manner as to cause the transport vehicle to exit out of the path via an exit section in the path.

2. The article transport facility according to claim 1, wherein, in a case where the number of transport vehicles targeted for the exit process due to respective inspection results being classified as the transport-unperformable abnormal level is less than a predetermined exit upper limit number, the control system performs the exit process on a transport vehicle having an inspection result classified as the transport-performable abnormal level until the number of transport vehicles subjected to the exit process reaches the exit upper limit number.

3. The article transport facility according to claim 1, wherein:
the inspection apparatus is configured to perform the inspection on each of the transport vehicles in terms of a plurality of inspection items,
the control system classifies itemized inspection results as respective inspection results on the plurality of inspection items into the normal level, the transport-performable abnormal level, and the transport-unperformable abnormal level and performs the exit process on a transport vehicle having at least one itemized inspection result classified as the transport-unperformable abnormal level, and
in a case where the number of transport vehicles targeted for the exit process due to at least one itemized inspection result being classified as the transport-unperformable abnormal level is less than a predetermined exit upper limit number, the control system performs the exit process preferentially on a transport vehicle having a larger number of inspection items whose itemized inspection results are classified as the transport-performable abnormal level, until the number of transport vehicles subjected to the exit process reaches the exit upper limit number.

4. The article transport facility according to claim 1, wherein:
the inspection apparatus is configured to perform the inspection on each of the transport vehicles in terms of a plurality of inspection items,
the control system classifies itemized inspection results as respective inspection results on the plurality of inspection items into the normal level and an abnormal level, and
the control system classifies an inspection result on a transport vehicle having at least one itemized inspection result classified as the abnormal level into the transport-performable abnormal level or the transport-unperformable abnormal level based on the number of inspection items whose itemized inspection results are classified as the abnormal level.

5. The article transport facility according to claim 1, wherein:
the control system restricts the number of transport vehicles to be targeted for the inspection performed by the inspection apparatus within a predetermined period to a predetermined inspection upper limit number or less.
